(19) United States
(12) Patent Application Publication
(10) Pub. No.: US 2023/0411524 A1
(43) Pub. Date: Dec. 21, 2023

(54) SEMICONDUCTOR STRUCTURE AND FORMING METHOD THEREOF

(71) Applicant: SEMICONDUCTOR MANUFACTURING NORTH CHINA (BEIJING) CORPORATION, Beijing (CN)

(72) Inventors: Jingang WANG, Beijing (CN); Zhenchao SUI, Beijing (CN)

(73) Assignee: SEMICONDUCTOR MANUFACTURING NORTH CHINA (BEIJING) CORPORATION, Beijing (CN)

(21) Appl. No.: 18/359,267

(22) Filed: Jul. 26, 2023

Related U.S. Application Data
(63) Continuation of application No. PCT/CN2021/073915, filed on Jan. 27, 2021.

(51) Int. Cl. H01L 29/78; H01L 29/04; H01L 29/66

(52) U.S. Cl. CPC H01L 29/7848; H01L 29/045; H01L 29/66545; H01L 29/66636; H01L 29/7834

(57) ABSTRACT

A semiconductor structure and a forming method thereof are provided. The semiconductor structure includes: a substrate, including a device cell area and an isolated area located on a periphery of the device cell area; an isolation structure, located in the substrate of the isolated area; a device gate structure, located on the substrate of the device cell area; and a source/drain doped layer, embedded into the substrate of the device cell area on two sides of the device gate structure, the source/drain doped layer including a source/drain bulk layer, a side wall of the source/drain bulk layer located on an edge of the device cell area and the isolation structure being spaced apart.

### CROSS REFERENCE TO RELATED APPLICATIONS

This application is a continuation application of PCT Patent Application No. PCT/CN2021/073915, filed on Jan. 27, 2021, the entire content of which is incorporated herein by reference.

### TECHNICAL FIELD

The disclosure relates to the field of semiconductor manufacturing, and in particular to a semiconductor structure and a forming method thereof.

### BACKGROUND

With the continuous development of integrated circuit technology, more devices will be integrated on the chip, and a higher speed will be used for the chip. With the advancement of these requirements, the geometric dimensions of devices will continue to decrease, and new materials, new technologies and new manufacturing processes will be constantly used in the manufacturing process of chips. The preparation of semiconductor devices has been developed to the nano-scale, and the preparation process of conventional devices has gradually matured.

In the field of semiconductors, the PMOS and the NMOS are typically treated separately in the manufacturing technology of CMOS devices. For example, a compressive stress material is used in a manufacturing method of a PMOS device, and a tensile stress material is used in an NMOS device, so that appropriate stress can be applied to the channel area, thereby improving the carrier mobility. Embedded silicon-germanium (SiGe) technology has become one of the main technologies in PMOS stress engineering due to its ability to apply appropriate compressive stress to the channel area to increase the hole mobility. According to the embedded SiGe process, an embedded SiGe layer is formed in the source/drain area to introduce the compressive stress to the channel. This stress distorts the crystal lattice of the semiconductor, such that uniaxial stress is generated in the channel area, thereby affecting the band alignment and the charge transport performance of the semiconductor. By controlling the size and distribution of stress in the final device, the hole mobility is improved, thereby improving the performance of the device.

However, the performance of current semiconductor structures still needs to be improved.

### SUMMARY

The present disclosure relates to a semiconductor structure and a forming method thereof. The side wall of the source/drain bulk layer located on the edge of the device cell area and the isolation structure are spaced apart, so that the side wall of the source/drain bulk layer located on the edge of the device cell area does not contact the isolation structure, which is beneficial to preventing doping ions in the source/drain bulk layer from diffusing into the isolation structure and preventing the extension resistance of the device from increasing, thereby improving the length of diffusion (LOD) effect and improving the performance of the semiconductor structure.

In an aspect of the disclosure, a semiconductor structure is provided. In one form, the semiconductor structure may include: a substrate, including a device cell area and an isolated area located on a periphery of the device cell area; an isolation structure, located in the substrate of the isolated area; a device gate structure, located on the substrate of the device cell area; and a source/drain doped layer, embedded into the substrate of the device cell area on two sides of the device gate structure, the source/drain doped layer including a source/drain bulk layer, a side wall of the source/drain bulk layer located on an edge of the device cell area and the isolation structure being spaced apart.

In another aspect of the disclosure, a method for forming a semiconductor structure is provided. In one form, the method may include: providing a substrate, including a device cell area and an isolated area located on a periphery of the device cell area; forming an isolation structure in the substrate of the isolated area; forming a gate structure on the substrate of the device cell area after the formation of the isolation structure; and forming a source/drain doped layer in the substrate of the device cell area on two sides of the gate structure, the source/drain doped layer including a source/drain bulk layer, a side wall of the source/drain bulk layer located on an edge of the device cell area and the isolation structure being spaced apart.

Compared with the prior art, the present disclosure has the following advantages: in the semiconductor structure described in the disclosure, the source/drain doped layer includes the source/drain bulk layer, and the side wall of the source/drain bulk layer located on the edge of the device cell area and the isolation structure are spaced apart, so that the side wall of the source/drain bulk layer located on the edge of the device cell area does not contact the isolation structure, which is beneficial to preventing doping ions in the source/drain bulk layer from diffusing into the isolation structure and accordingly preventing the extension resistance of the device from increasing, thereby improving the length of diffusion (LOD) effect and improving the performance of the semiconductor structure.

In some forms, in the step of forming the source/drain doped layer, the source/drain doped layer includes the source/drain bulk layer, and the side wall of the source/drain bulk layer located on the edge of the device cell area and the isolation structure are spaced apart, so that the side wall of the source/drain bulk layer located on the edge of the device cell area does not contact the isolation structure, which is beneficial to preventing doping ions in the source/drain bulk layer from diffusing into the isolation structure and accordingly preventing the extension resistance of the device from increasing, thereby improving the LOD effect and improving the performance of the semiconductor structure.

In some forms, during the formation of the source/drain doped layer, the side wall of the source/drain bulk layer located on the edge of the device cell area has an included angle with the isolation structure and forms a trench with the isolation structure; and the forming method of a semiconductor structure further includes: forming a cap layer filling the trench and covering the surface of the source/drain bulk layer after the formation of the source/drain doped layer, a material of the cap layer being a silicon-containing semiconductor material. Thus, the cap layer can prevent the source/drain bulk layer from contacting the isolation structure and accordingly prevent the source/drain bulk layer from contacting an isolation material, thereby effectively reducing the extension resistance of the device and improving the LOD effect.

In some forms, the forming method of a semiconductor structure further includes: conformally covering surfaces of the isolation structure, the cap layer and the gate structure with a stress layer after the formation of the cap layer. The stress layer is beneficial to maintaining the stress in the source/drain bulk layer, so that all the stress of the source/drain bulk layer can be applied to the channel, which prevents stress loss of the source/drain doped layer, thereby ensuring the improvement of the carrier mobility in the channel area and further improving the performance of the semiconductor structure.

### BRIEF DESCRIPTION OF THE DRAWINGS

FIG. 1 to FIG. 3 are schematic structural diagrams of a semiconductor structure;

FIG. 4 to FIG. 5 are schematic structural diagrams of a semiconductor structure according to an example of the disclosure; and

FIG. 6 to FIG. 25 are schematic structural diagrams corresponding to steps of a forming method of a semiconductor structure according to an example of the disclosure.

### DETAILED DESCRIPTION

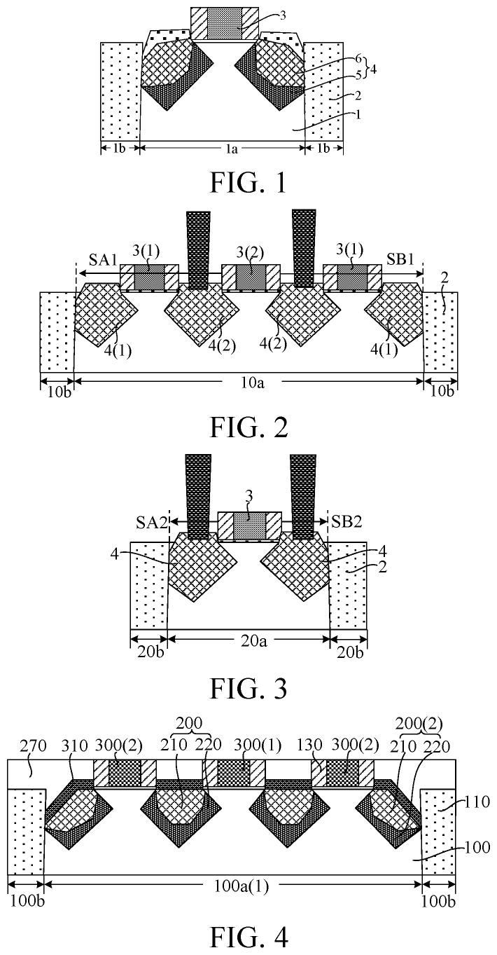

According to the Background, the performance of the current semiconductor structures still needs to be improved. The reasons why the performance of the semiconductor structure still needs to be improved will be analyzed in conjunction with a semiconductor structure. FIG. 1 to FIG. 3 are schematic structural diagrams of a semiconductor structure.

Referring to FIG. 1, the semiconductor structure includes: a substrate 1, including a device cell area 1a and an isolated area 1b located on a periphery of the device cell area 1a; an isolation structure 2, located in the substrate 1 of the isolated area 1b; a gate structure 3, located on the substrate 1 of the device cell area 1a; and a source/drain doped layer 4, located in the substrate 1 of the device cell area 1a on two sides of the gate structure 3, the source/drain doped layer 4 including a source/drain seed layer 5 and a source/drain bulk layer 6 located on the source/drain seed layer 5, and a side wall of the source/drain bulk layer 6 located on an edge of the device cell area 1a contacting the isolation structure 2. The source/drain bulk layer 6 is a heavily doped layer, and a doping content of the source/drain bulk layer 6 is higher than a doping content of the source/drain seed layer 5.

In an example, the semiconductor structure is used for forming a PMOS device. In order to improve the performance of the PMOS device, the source/drain doped layer 4 is an embedded SiGe layer. The SiGe layer can apply compressive stress to the channel area, thereby improving the hole mobility.

However, it is difficult for the embedded SiGe layer to improve the length of diffusion (LOD) effect of the PMOS device.

Specifically, FIG. 2 and FIG. 3 respectively show a first device cell area 10a for forming a first device and a second device cell area 20a for forming a second device. The first device cell area 10a and the second device cell area 20a are different in that: in the first device cell area 10a, the number of the gate structures 3 is plural, including a central gate structure 3(2) and an edge gate structure 3(1) located on an edge of the first device cell area 10a; the source/drain doped layer 4 located on two sides of the central gate structure 3(2) is used as a central source/drain doped layer 4(2), and the source/drain doped layer 4 located on the edge of the first device cell area 10a is used as an edge source/drain doped layer 4(1); accordingly, the source/drain doped layer 4 of the first device corresponding to the central gate structure 3(2) does not contact the isolation structure 2, and the edge source/drain doped layer 4(1) contacts the isolation structure 2; and in the second device cell area 20a, the number of the gate structures 3 is only one, and a side wall of the source/drain doped layer 4 of the second device contacts the isolation structure 2.

Therefore, a distance SA1 or SB1 from the central gate structure 3(2) of the first device cell area 10a to the isolated area 10b is different a distance SA2 or SB2 from the gate structure 3 of the second device cell area 20a to the isolated area 20b. Moreover, the side wall of the source/drain doped layer 4 of the second device cell area 20a contacts the isolation structure 2, so that doping ions in the source/drain doped layer 4 may easily diffuse into the isolation structure 2, causing the extension resistance of the second device to increase and further affecting the performance of the device. Besides, a structural integrity of the central source/drain doped layer 4(2) of the first device cell area 10a is greater than a structural integrity of the source/drain doped layer 4 of the second device cell area 20a, and a volume of the central source/drain doped layer 4 of the first device cell area 10a is greater than a volume of the source/drain doped layer 4 of the second device cell area 20a.

Based on the above analysis, the performance of the first device is quite different from the performance of the second device. The extension resistance of the second device is higher than the extension resistance of the first device, so that the performance (such as saturation current, threshold voltage) of the first device is quite different from the performance of the second device. Therefore, it is difficult to improve the LOD effect of the device, and in particular, the performance of the second device is poor.

To solve the technical problems, an example of the disclosure provides a forming method of a semiconductor structure, including: a substrate, including a device cell area and an isolated area located on a periphery of the device cell area; an isolation structure, located in the substrate of the isolated area; a device gate structure, located on the substrate of the device cell area; and a source/drain doped layer, embedded into the substrate of the device cell area on two sides of the device gate structure, the source/drain doped layer including a source/drain bulk layer, a side wall of the source/drain bulk layer located on an edge of the device cell area and the isolation structure being spaced apart.

In the semiconductor structure provided by the example of the disclosure, the side wall of the source/drain bulk layer located on the edge of the device cell area and the isolation structure are spaced apart, so that the side wall of the source/drain bulk layer located on the edge of the device cell area does not contact the isolation structure, which is beneficial to preventing doping ions in the source/drain bulk layer from diffusing into the isolation structure and accordingly preventing the extension resistance of the device from increasing, thereby improving the LOD effect and improving the performance of the semiconductor structure.

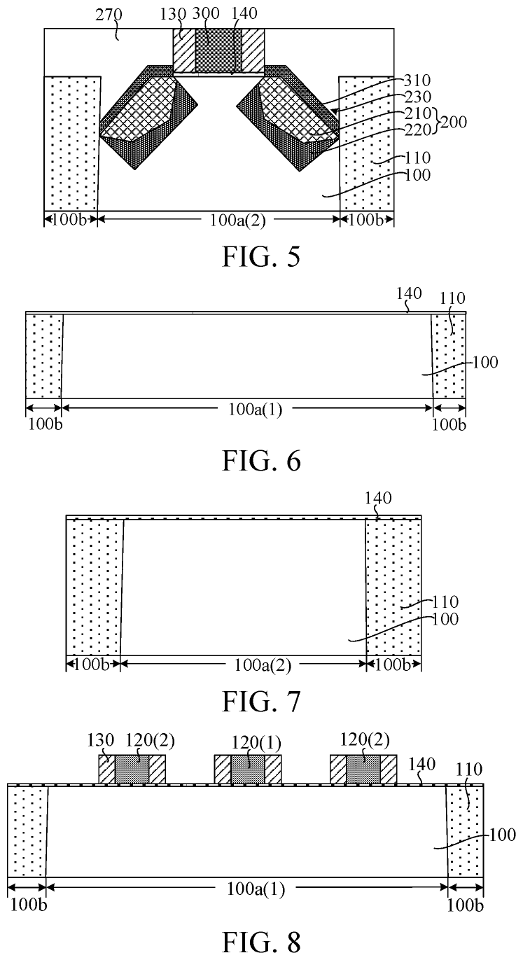

To make the foregoing objectives, features, and advantages of the examples of the disclosure more apparent and easier to understand, specific examples of the disclosure are described in detail below with reference to the accompanying drawings. FIG. 4 and FIG. 5 show schematic structural diagrams of a semiconductor structure according to an example of the disclosure.

In this example, the semiconductor structure includes: a substrate 100, including a device cell area 100a and an isolated area 100b located on a periphery of the device cell area 100a; an isolation structure 110, located in the substrate 100 of the isolated area 100b; a device gate structure 300, located on the substrate 100 of the device cell area 100a; and a source/drain doped layer 200, embedded into the substrate 100 of the device cell area 100a on two sides of the device gate structure 300, the source/drain doped layer 200 including a source/drain bulk layer 210, and a side wall of the source/drain bulk layer 210 located on an edge of the device cell area 100a and the isolation structure 110 being spaced apart.

The substrate 100 is used for providing a process platform for the formation of the semiconductor structure.

The device cell area 100a is used for forming a device. The isolated area 100b is used for realizing isolation between the device cell areas 100a.

In this example, the substrate 100 includes a first device cell area 100a(1) for forming a first device and a second device cell area 100a(2) for forming a second device. Peripheries of the first device cell area 100a(1) and the second device cell 100(2) are provided with the isolated area 100b. The device cell area 100a accordingly includes the first device cell area 100a(1) and the second device cell area 100a(2).

In this example, the first device and the second device are devices having different layout types in integrated circuit design.

In this example, the substrate 100 is a planar substrate. In this example, the substrate 100 is a silicon base. In other examples, the material of the substrate may also be germanium, silicon-germanium, silicon carbide, gallium arsenide, indium-gallium or other materials. In some other examples, according to the type of transistor to be formed, the substrate may also be a three-dimensional substrate. For example, the substrate may include a base and fins located on the base.

The isolation structure 110 is used for realizing isolation between the device cell areas 100.

In this example, the isolation structure 110 is a shallow trench isolation (STI) structure, and a material of the isolation structure 110 is silicon oxide. In other examples, the material of the isolation structure may also be other dielectric material such as silicon nitride, silicon oxynitride or the like.

In this example, an isolation trench (not shown) is formed in the substrate 100 of the isolated area 100b, and the isolation structure 110 fills the isolation trench. The isolation trench is used for providing a space position for the formation of the isolation structure 110, and the isolation trench is also used for defining an active area (AA) and the isolated area 100b of the substrate 100.

During the operation of the device, the device gate structure 300 is used for controlling a conductive channel to be on or off.

In this example, the device gate structure 300 is a metal gate structure, and the device gate structure 300 includes a high k gate dielectric layer (not shown), a work function layer (not shown) and a metal gate electrode layer (not shown) sequentially stacked from bottom to top.

A material of the high k gate dielectric layer is a high k dielectric material. The high k dielectric material is a dielectric material with a relative dielectric constant of greater than a relative dielectric constant of the silicon oxide. Specifically, the material of the high k gate dielectric layer is HfO₂. In other examples, the material of the high k gate dielectric layer may also be selected from ZrO₂, HfSiO, HfSiON, HfTaO, HfSiO, HfZrO, Al₂O₃ or the like.

The work function layer is used for adjusting a work function of the device gate structure 300, thereby adjusting the threshold voltage of the device. When forming a PMOS device, the work function layer is a P-type work function layer, and a material of the P-type work function layer includes one or more of TiN, Ta, TaN, TaSiN and TiSiN. When forming an NMOS device, the work function layer is an N-type work function layer, and a material of the N-type work function layer includes one or more of TiAl, TaAlN, TiAlN, MoN, TaCN and AlN.

The gate electrode layer, serving as an electrode, is used for electrically leading out the device gate structure 300, so that the device gate structure 300 can be electrically connected to an external circuit or other interconnect structures. A material of the gate electrode layer is a conductive material. The material of the gate electrode layer is Al, Cu, Ag, Au, Pt, Ni, Ti or W. In this example, the material of the gate electrode layer is W.

In other examples, the device gate structure may also be a poly gate structure. Accordingly, the device gate structure may include a poly gate layer.

In this example, the number of the device gate structures 300 located in the first device cell area 100a(1) is plural; and the number of the device gate structures 300 located in the second device cell area 100a(2) is one.

In this example, in the first device cell area 100a(1), the device gate structure 300 includes a central device gate 300(1) and an edge device gate 300(2) located on an edge of the first device cell area 100a(1).

In this example, the semiconductor structure further includes: a gate oxide layer 140, located between the device gate structure 300 and the substrate 100. The gate oxide layer 140 is used for realizing isolation between the device gate structure 300 and the channel. In this example, a material of the gate oxide layer 140 is silicon oxide or silicon oxynitride.

In this example, the semiconductor structure further includes: a spacer 130, located on a side wall of the device gate structure 300. The spacer 130 is used for protecting the side wall of the device gate structure 300, and also used for defining a formation position of the source/drain doped layer 200. In this example, the spacer 130 also covers the gate oxide layer 140.

The spacer 130 may be a single-layer or laminated structure. In an example, the spacer 130 is a laminated structure, and the spacer 130 includes a first silicon oxide layer (not shown) located on the side wall of the device gate structure 300, a silicon nitride layer (not shown) located on the first silicon oxide layer, and a second silicon oxide layer (not shown) located on a side wall of the silicon nitride layer.

During the operation of the device, the source/drain doped layer 200 is used for providing a carrier source. In this example, the source/drain doped layer 200 is also used for providing stress for the channel area, thereby improving the carrier mobility.

The source/drain doped layer 200 includes a source/drain bulk layer 210. The source/drain bulk layer 210 has a higher doping content and a larger volume. If the source/drain bulk layer 210 is not adjusted, there will be a high risk of diffusion of doping ions in the source/drain bulk layer 210 located on the edge of the device cell area 100a into the isolation structure 110, which easily causes the extension resistance of the device to increase and significantly affects the performance of the device.

Therefore, in this example, the side wall of the source/drain bulk layer 210 located on the edge of the device cell area 100a and the isolation structure 110 are spaced apart, so that the side wall of the source/drain bulk layer 210 located on the edge of the device cell area 100a does not contact the isolation structure 110, which is beneficial to preventing doping ions in the source/drain bulk layer 210 from diffusing into the isolation structure 110 and accordingly preventing the extension resistance of the device from increasing, thereby improving the length of diffusion (LOD) effect and improving the performance of the semiconductor structure.

In this example, the side wall of the source/drain bulk layer 210 located on the edge of the device cell area 100a has an included angle with the isolation structure 110, and the side wall of the source/drain bulk layer 210 located on the edge of the device cell area 100a forms a trench 230 with the isolation structure 110.

Specifically, in this example, the side wall of the source/drain bulk layer 210 located on the edge of the device cell area 100a on a side opposite to the isolation structure 110 is a Miller index plane <111>, also referred to as a <111> plane, so that the side wall of the source/drain bulk layer 210 located on the edge of the device cell area 100a has an included angle of 45° or so with the surface of the substrate 100, thereby preventing the side wall of the source/drain bulk layer 210 located on the edge of the device cell area 100a from contacting the isolation structure 110.

In an example, the substrate 100 of the device cell area 100a is used for forming a PMOS device, and a material of the source/drain doped layer 200 includes SiGe.

When using the SiGe material, since a lattice constant of Ge is greater than a lattice constant of Si, there is a lattice mismatch between Si and Ge, so that a lattice constant of the SiGe is greater than that of Si. Therefore, the source/drain doped layer 200 can generate compressive stress toward the channel, which thereby is beneficial to improving the hole mobility and improves the current driving ability and circuit speed. Moreover, the SiGe material is sensitive to the environment. When the SiGe is used as a material of the source/drain doped layer 200 of a PMOS device in the existing process, it is always difficult to improve the LOD effect of the PMOS device. In this example, by adjusting the morphology of the source/drain bulk layer 210, the side wall of the source/drain bulk layer 210 located on the edge of the device cell area 100a and the isolation structure 110 are spaced apart, which is beneficial to significantly improving the performance of the PMOS device.

In other examples, when forming an NMOS device, a material of the source/drain doped layer includes SiC. Since a lattice constant of C is greater than the lattice constant of Si, there is a lattice mismatch between Si and C, so that a lattice constant of the SiC is greater than that of Si. Moreover, since the lattice constant of C is much smaller than the lattice constant of Si, the SiC can obtain very high stress with very few carbon atoms, so the source/drain doped layer can generate tensile stress on the lateral channel, which thereby is beneficial to improving the electron mobility.

The source/drain doped layer 200 is doped with ions. In this example, in an example where a PMOS device is formed, the source/drain doped layer 200 is doped with P-type ions, and the P-type ions may be B ions, Ga ions or In ions. In other examples, when forming an NMOS device, the source/drain doped layer is correspondingly doped with N-type ions, and the N-type ions may be P ions, As ions or Sb ions.

In this example, the semiconductor structure includes: a groove 260 (referring to FIG. and FIG. 11), located in the substrate 100 of the device cell area 100a on the two sides of the device gate structure 300. The source/drain doped layer 200 is located in the groove 260.

The groove 260 is used for providing a space position for the formation of the source/drain doped layer 200. The groove 260 is formed by etching the substrate 100 of the device cell area 100a on the two sides of the device gate structure 200.

In this example, the groove 260 is a Σ structure. The source/drain doped layer 200 is epitaxially grown in the groove 260, and the groove 260 is a Σ structure, so that the surface of the substrate 100 exposed by the groove 260 includes a Miller index orientation <111>, also referred to as a <111> orientation. Thereby, during the epitaxy growth of the source/drain doped layer 200, the source/drain bulk layer 210 can be epitaxially grown along the <111> orientation selectively, so that the growth morphology of the source/drain bulk layer 210 can be adjusted, thereby preventing the source/drain bulk layer 210 located on the edge of the device cell area 100a from growing in a direction close to the isolation structure 110, and accordingly ensuring the side wall of the source/drain bulk layer 210 located on the edge of the device cell area 100a and the isolation structure 110 to be spaced apart.

In this example, the source/drain doped layer 200 further includes: a source/drain seed layer 220, located between the substrate 100 exposed by the groove 260 and the source/drain bulk layer 210. A doping content of the source/drain seed layer 220 is lower than a doping content of the source/drain bulk layer 210.

The source/drain seed layer 220 is used as an epitaxial seed layer for the formation of the source/drain bulk layer 210, i.e., the source/drain bulk layer 210 is formed by epitaxy growth on the basis of the source/drain seed layer 220. Moreover, the source/drain seed layer 220 is beneficial to improving the defects on the side wall and bottom wall of the groove 260, thereby improving the epitaxy growth quality of the source/drain bulk layer 210. Besides, the source/drain seed layer 220 is also used for isolating the source/drain bulk layer 210 with high doping content from the substrate 100, thereby significantly reducing the probability of diffusion of doping ions in the source/drain bulk layer 210 into the substrate 100.

In this example, the doping content and volume of the source/drain seed layer 220 are respectively less than the doping content and volume of the source/drain bulk layer 210, and the probability of contact between the source/drain seed layer 220 located on the edge of the device cell area 100a and the isolation structure 110 and the probability of diffusion of doping ions in the source/drain seed layer 220 into the isolation structure 110 are both low. Thereby, in this example, by adjusting the morphology of the source/drain bulk layer 210, the source/drain bulk layer 210 located on the edge of the device cell area 100a does not contact the isolation structure 110, which is beneficial to significantly reducing the probability of diffusion of doping ions in the source/drain doped layer 200 into the isolation structure 110 and improving the LOD effect. Moreover, there is no need to adjust the morphology of the source/drain seed layer 220, which is beneficial to improving the compatibility with the existing process.

It would be appreciated that in the first device cell area 100a(1), the device gate structure 300 includes a central device gate 300(1) and an edge device gate 300(2) located on an edge of the first device cell area 100a(1). Accordingly, the source/drain doped layer 200 located between the edge device gate 300(2) and the isolated area 100b is used as an edge source/drain doped layer 200(2), so that the source/drain doped layer 200 of the first device corresponding to the central device gate 300(1) is away from the isolation structure 110, thereby accordingly ensuring the integrity of the source/drain doped layer 200 of the first device corresponding to the central device gate 300(1).

In the second device cell area 100a(2), the number of the device gate structures 300 is one, and the source/drain doped layer 200 of the second device is located on the edge of the second device cell area 100a(2) and close to the isolation structure 110.

Accordingly, in this example, by adjusting the morphology of the source/drain bulk layer 210, the side wall of the source/drain bulk layer 210 located on the edge of the device cell area 100a and the isolation structure 110 are spaced apart so as to prevent the source/drain bulk layer 210 of the second device from contacting the isolation structure 110, thereby being beneficial to significantly improving the performance of the second device, especially when the second device is a PMOS device.

In this example, the side wall of the source/drain bulk layer 210 located on the edge of the device cell area 100a forms a trench 230 with the isolation structure 110.

In this example, the semiconductor structure further includes: a metal silicide layer 310, located in the trench 230 and covering a surface of the source/drain bulk layer 210.

The metal silicide layer 310 is used for reducing a contact resistance between the source/drain doped layer 200 and a source/drain contact plug (not shown). A material of the metal silicide layer 310 may be a nickel silicon compound, a cobalt silicon compound or a titanium silicon compound.

In this example, during the formation of the semiconductor structure, before the metal silicide layer 310 is formed, a cap layer covering the surface of source/drain bulk layer 210 is also formed in the trench 230; and during the salicide process, the metal silicide layer 310 is formed by a reaction between the cap layer and a metal layer.

A material of the cap layer is a silicon-containing semiconductor material. The cap layer of which the material is the silicon-containing semiconductor material arranged in the trench 230 can prevent the source/drain bulk layer 210 from contacting the isolation structure 110 during the formation of the semiconductor structure, and accordingly prevent the source/drain bulk layer 210 from contacting the isolation material, thereby effectively reducing the extension resistance of the device and improving the LOD effect.

In this example, during the formation of the metal silicide layer 310, the cap layer completely reacts with the metal layer and is transformed into the metal silicide layer 310, so no residual cap layer remains in the semiconductor structure.

In other examples, during the formation of the semiconductor structure, a side wall layer is further formed on a side wall of the spacer. When the side wall layer also covers a top surface of a part of the cap layer, this part of the cap layer does not react with the metal layer under the coverage of the side wall layer. Accordingly, the semiconductor structure further includes the side wall layer located on the side wall of the spacer, and the cap layer located between a bottom of the side wall layer and the source/drain doped layer.

In this example, the semiconductor structure further includes: an interlayer dielectric layer 270, located on the substrate 100 on a side of the device gate structure 300. In this example, the interlayer dielectric layer 270 covers the side wall of the spacer 130 and a surface of the metal silicide layer 310, and the interlayer dielectric layer 270 also fills the trench 230.

The interlayer dielectric layer 270 is used for realizing electrical isolation between adjacent devices. A material of the interlayer dielectric layer 270 is a dielectric material. In this example, the material of the interlayer dielectric layer 270 is silicon oxide.

Accordingly, the disclosure further provides a forming method of a semiconductor structure. FIG. 6 to FIG. 25 are schematic structural diagrams corresponding to steps of a forming method of a semiconductor structure according to an example of the disclosure. The forming method of a semiconductor structure in this example will be described in detail below in conjunction with the accompanying drawings.

Referring to FIG. 6 and FIG. 7, a substrate 100 is provided, including a device cell area 100a and an isolated area 100b located on a periphery of the device cell area 100a. The substrate 100 is used for providing a process platform for the subsequent process.

The device cell area 100a is used for forming a device. The isolated area 100b is used for realizing isolation between the device cell areas 100a.

In this example, the substrate 100 includes a first device cell area 100a(1) for forming a first device and a second device cell area 100a(2) for forming a second device. Peripheries of the first device cell area 100a(1) and the second device cell 100(2) are provided with the isolated area 100b. The device cell area 100a accordingly includes the first device cell area 100a(1) and the second device cell area 100a(2).

In this example, the first device and the second device are devices having different layout types in integrated circuit design.

In this example, the substrate 100 is a planar substrate. In this example, the substrate 100 is a silicon base. In other examples, the material of the substrate may also be germanium, silicon-germanium, silicon carbide, gallium arsenide, indium-gallium or other materials. In some other examples, according to the type of transistor to be formed, the substrate may also be a three-dimensional substrate. For example, the substrate may include a base and fins located on the base.

Referring to FIG. 6 and FIG. 7, an isolation structure 110 is formed in the substrate 100 of the isolated area 100b.

The isolation structure 110 is used for realizing isolation between the device cell areas 100a.

In this example, the isolation structure 110 is a shallow trench isolation (STI) structure, and a material of the isolation structure 110 is silicon oxide. In other examples, the material of the isolation structure may also be other dielectric material such as silicon nitride, silicon oxynitride or the like.

In this example, the step of forming the isolation structure 110 includes: an isolation structure (not shown) is formed in the substrate 100 of the isolated area 100b; and the isolation structure 110 is formed in the isolation trench.

The isolation trench is used for providing a space position for the formation of the isolation structure 110, and the isolation trench is also used for defining an active area (AA) and the isolated area 100b of the substrate 100.

Specifically, the step of forming the isolation structure 110 in the isolation trench includes: the isolation trench is filled with an isolation material layer (not shown), the isolation material layer further covering a top surface of the substrate 100; and the isolation material layer located on the top surface of the substrate 100 is removed, the remaining isolation material layer located in the isolation trench being used as the isolation structure 110.

In this example, the forming method of a semiconductor structure further includes: forming a gate oxide layer 140 on the top surface of the substrate 100. The gate oxide layer 140 is used for realizing isolation between the device gate structure and the channel. In this example, a material of the gate oxide layer 140 is silicon oxide or silicon oxynitride.

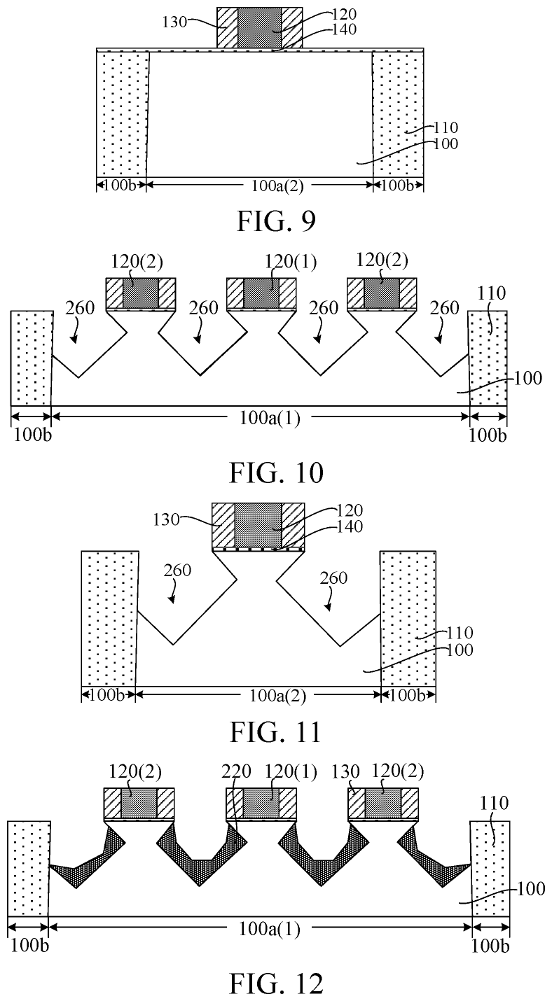

Referring to FIG. 8 and FIG. 9, after the formation of the isolation structure 110, a gate structure 120 is formed on the substrate 100 of the device cell area 100a. In this example, the gate structure 120 is formed on the gate oxide layer 140.

In this example, the gate structure 120 is a dummy gate used for occupying a space position for subsequent formation of the device gate structure. In this example, the gate structure 120 is a poly gate structure. The gate structure 120 includes a poly gate layer.

In this example, in the step of forming the gate structure 120, the number of the gate structures 120 formed in the first device cell area 100a(1) is plural; and the number of the gate structures 120 formed in the second device cell area 100a(2) is one. In this example, in the first device cell area 100a(1), the gate structure 120 includes a central gate 120(1) and an edge gate 120(2) located on an edge of the first device cell area 100a(1).

In this example, the forming method of a semiconductor structure further includes: a spacer 130 is formed on a side wall of the gate structure 120.

The spacer 130 is used for protecting the side wall of the gate structure 120, and the spacer 130 is also used for defining a formation position of the source/drain doped layer. In this example, the spacer 130 also covers a part of the gate oxide layer 140.

The spacer 130 is a single-layer or laminated structure. In an example, the spacer 130 is a laminated structure, and the spacer 130 includes a first silicon oxide layer (not shown) located on the side wall of the gate structure 120, a silicon nitride layer (not shown) located on the first silicon oxide layer, and a second silicon oxide layer (not shown) located on a side wall of the silicon nitride layer.

Referring to FIG. 10 to FIG. 15, a source/drain doped layer 200 is formed in the substrate 100 of the device cell area 100a on two sides of the gate structure 120. The source/drain doped layer 200 includes a source/drain bulk layer 210, and a side wall of the source/drain bulk layer 210 located on an edge of the device cell area 100a and the isolation structure 110 are spaced apart.

During the operation of the device, the source/drain doped layer 200 is used for providing a carrier source. In this example, the source/drain doped layer 200 is also used for providing stress for the channel area, thereby improving the carrier mobility.

The source/drain bulk layer 210 has a higher doping content and a larger volume. If the source/drain bulk layer 210 is not adjusted, there will be a high risk of diffusion of doping ions in the source/drain bulk layer 210 located on the edge of the device cell area 100a into the isolation structure 110, which easily causes the extension resistance of the device to increase and significantly affects the performance of the device.

Therefore, in this example, the side wall of the source/drain bulk layer 210 located on the edge of the device cell area 100a and the isolation structure 110 are spaced apart, so that the side wall of the source/drain bulk layer 210 located on the edge of the device cell area 100a does not contact the isolation structure 110, which is beneficial to preventing doping ions in the source/drain bulk layer 210 from diffusing into the isolation structure 110 and accordingly prevent the extension resistance of the device from increasing, thereby improving the length of diffusion (LOD) effect and improving the performance of the semiconductor structure.

Specifically, by adjusting the growth morphology of the source/drain bulk layer 210, the side wall of the source/drain bulk layer 210 located on the edge of the device cell area 100a and the isolation structure 110 are spaced apart.

In an example, in this example, the substrate 100 of the device cell area 100a is used for forming a PMOS device, and a material of the source/drain doped layer 200 includes SiGe.

When using the SiGe material, since a lattice constant of Ge is greater than a lattice constant of Si, there is a lattice mismatch between Si and Ge, so that a lattice constant of the SiGe is greater than that of Si. Therefore, the source/drain doped layer 200 can generate compressive stress toward the channel, which thereby is beneficial to improving the hole mobility and improves the current driving ability and circuit speed. Moreover, the SiGe material is sensitive to the environment. When the SiGe is used as a material of the source/drain doped layer 200 of a PMOS device in the existing process, it is always difficult to improve the LOD effect of the PMOS device. In this example, by adjusting the morphology of the source/drain bulk layer 210, the side wall of the source/drain bulk layer 210 located on the edge of the device cell area 100a and the isolation structure 110 are spaced apart, which is beneficial to significantly improving the performance of the PMOS device.

In other examples, when forming an NMOS device, a material of the source/drain doped layer includes SiC. Since a lattice constant of C is greater than the lattice constant of Si, there is a lattice mismatch between Si and C, so that a lattice constant of the SiC is greater than that of Si. Moreover, since the lattice constant of C is much smaller than the lattice constant of Si, the SiC can obtain very high stress with very few carbon atoms, so the source/drain doped layer can generate tensile stress on the lateral channel, which thereby is beneficial to improving the electron mobility.

The source/drain doped layer 200 is doped with ions. In this example, in an example where a PMOS device is formed, the source/drain doped layer 200 is doped with P-type ions, and the P-type ions may be B ions, Ga ions or In ions. In other examples, when forming an NMOS device, the source/drain doped layer is correspondingly doped with N-type ions, and the N-type ions may be P ions, As ions or Sb ions.

The step of forming the source/drain doped layer 200 in this example will be described in detail below in conjunction with the accompanying drawings.

As shown in FIG. 10 and FIG. 11, a groove 260 is formed in the substrate 100 of the device cell area 100a on the two sides of the gate structure 120. The groove 260 located on the edge of the device cell area 100a exposes a part of the side wall of the isolation structure 110. The groove 260 is used for providing a space position for the formation of the source/drain doped layer.

In this example, during the formation of the groove 260, the gate oxide layer 140 on the top surface of the substrate 100 located on the two sides of the gate structure 120 is also removed by etching.

Specifically, the substrate 100 of the device cell area 100a on the two sides of the gate structure 120 is etched sequentially by a dry etching process and a wet etching process to form the groove 260.

In this example, during the formation of the groove 260, the groove 260 is a Σ structure.

The source/drain doped layer is epitaxially grown in the groove 260 subsequently, and the groove 260 is a Σ structure, so that the surface of the substrate 100 exposed by the groove 260 includes a <111> orientation. Thereby, during the epitaxy growth of the source/drain doped layer, the source/drain bulk layer can be epitaxially grown along the <111> orientation selectively. The source/drain bulk layer is not epitaxially grown on the side wall of the isolation structure 110 exposed by the groove 260, thereby accordingly preventing the source/drain bulk layer located on the edge of the device cell area 100a from growing in a direction close to the isolation structure 110, and ensuring the source/drain bulk layer located on the edge of the device cell area 100a and the isolation structure 110 to be spaced apart.

As shown in FIG. 12 to FIG. 15, the source/drain doped layer 200 is formed in the groove 260.

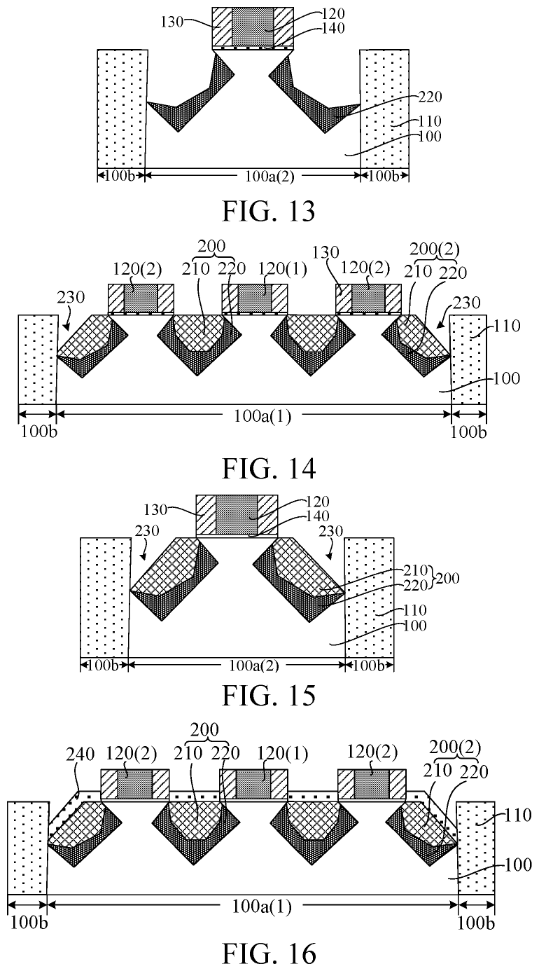

Specifically, the step of forming the source/drain doped layer 200 in the groove 260 includes: as shown in FIG. 12 and FIG. 13, a source/drain seed layer 220 is formed on a surface of the substrate 100 exposed by the groove 260; and as shown in FIG. 14 and FIG. 15, a source/drain bulk layer 210 is formed on the source/drain seed layer 220, a doping content of the source/drain bulk layer 210 being higher than the doping content of the source/drain seed layer 220.

Therefore, in this example, the source/drain doped layer 200 includes the source/drain seed layer 220 contacting the surface of the substrate 100 exposed by the groove 260 and the source/drain bulk layer 210 located on the source/drain seed layer 220.

The source/drain seed layer 220 is used as an epitaxial seed layer for the formation of the source/drain bulk layer 210, i.e., the source/drain bulk layer 210 is formed by epitaxy growth on the basis of the source/drain seed layer 220. Moreover, the source/drain seed layer 220 is beneficial to improving the defects on the side wall and bottom wall of the groove 260, thereby improving the epitaxy growth quality of the source/drain bulk layer 210. Besides, the source/drain seed layer 220 is also used for isolating the source/drain bulk layer 210 with high doping content from the substrate 100, thereby reducing the probability of diffusion of doping ions in the source/drain bulk layer 210 into the substrate 100.

In this example, the doping content and volume of the source/drain seed layer 220 are respectively less than the doping content and volume of the source/drain bulk layer 210, and the probability of contact between the source/drain seed layer 220 located on the edge of the device cell area 100a and the isolation structure 110 and the probability of diffusion of doping ions in the source/drain seed layer 220 into the isolation structure 110 are both low. Thereby, in this example, by adjusting the morphology of the source/drain bulk layer 210, the source/drain bulk layer 210 located on the edge of the device cell area 100a does not contact the isolation structure 110, which can significantly reduce the probability of diffusion of source/drain doping ions into the isolation structure 110 and improve the LOD effect. Moreover, there is no need to adjust the forming process and growth morphology of the source/drain seed layer 220, which is beneficial to improving the compatibility with the existing process.

In this example, the source/drain seed layer 220 is formed by a selective epitaxy growth (SEG) process.

In this example, after the formation of the source/drain seed layer 220, an epitaxial layer is formed by an epitaxy growth process, ions are autodoped in situ during the formation of the epitaxial layer to form the source/drain bulk layer 210.

In this example, the step of forming the source/drain bulk layer 210 includes: recipes of the epitaxy growth process are adjusted such that the source/drain bulk layer 210 is epitaxially grown along a <111> orientation.

By epitaxially growing the source/drain bulk layer 210 along the <111> orientation, the growth morphology of the source/drain bulk layer 210 located on the edge of the device cell area 100a is adjusted, so that the side wall of the source/drain bulk layer 210 located on the edge of the device cell area 100a accordingly has an included angle with the side wall of the isolation structure 110, thereby preventing the side wall of the source/drain bulk layer 210 located on the edge of the device cell area 100a from contacting the isolation structure 110.

In this example, a side of the groove 260 located on the edge of the device cell area 100a exposes a part of the side wall of the isolation structure 110; during the epitaxy growth process of forming the source/drain bulk layer 210, the source/drain bulk layer 210 located on the edge of the device cell area 100a is not epitaxially grown on the side wall of the isolation structure 110 exposed by the groove 260; and accordingly, after the formation of the source/drain bulk layer 210, the side wall of the source/drain bulk layer 210 located on the edge of the device cell area 100a on a side opposite to the isolation structure 110 is a <111> plane, so that the source/drain bulk layer 210 located on the edge of the device cell area 100a does not contact the isolation structure 110.

Specifically, the adjusting the recipes of the epitaxy growth process may include: process parameters, such as reactant gas flow rate, temperature, pressure, etc., of the epitaxy growth process are adjusted so that the source/drain bulk layer 210 can be epitaxially grown along the <111> orientation.

It would be appreciated that in the first device cell area 100a(1), the gate structure 120 includes a central gate 120(1) and an edge gate 120(2). Accordingly, the source/drain doped layer 200 located between the edge gate 120(2) and the isolated area 100b is used as an edge source/drain doped layer 200(2), so that the source/drain doped layer 200 of the first device corresponding to the central gate 120(1) is away from the isolation structure 110, thereby accordingly ensuring the integrity of the source/drain doped layer 200 of the first device.

In the second device cell area 100a(2), the number of the gate structures 120 is one, and the source/drain doped layer 200 of the second device is located on the edge of the second device cell area 100a(2) and close to the isolation structure 110. Accordingly, in this example, by adjusting the morphology of the source/drain bulk layer 210, the side wall of the source/drain bulk layer 210 located on the edge of the device cell area 100a and the isolation structure 110 are spaced apart, which is beneficial to preventing the source/drain bulk layer 210 of the second device from contacting the isolation structure 110, thereby being beneficial to significantly improving the performance of the second device, especially when the second device is a PMOS device.

In this example, during the formation of the source/drain doped layer 200, the side wall of the source/drain bulk layer 210 located on the edge of the device cell area 100a has an included angle with the isolation structure 110, and the side wall of the source/drain bulk layer 210 located on the edge of the device cell area 100a forms a trench 230 with the isolation structure 110.

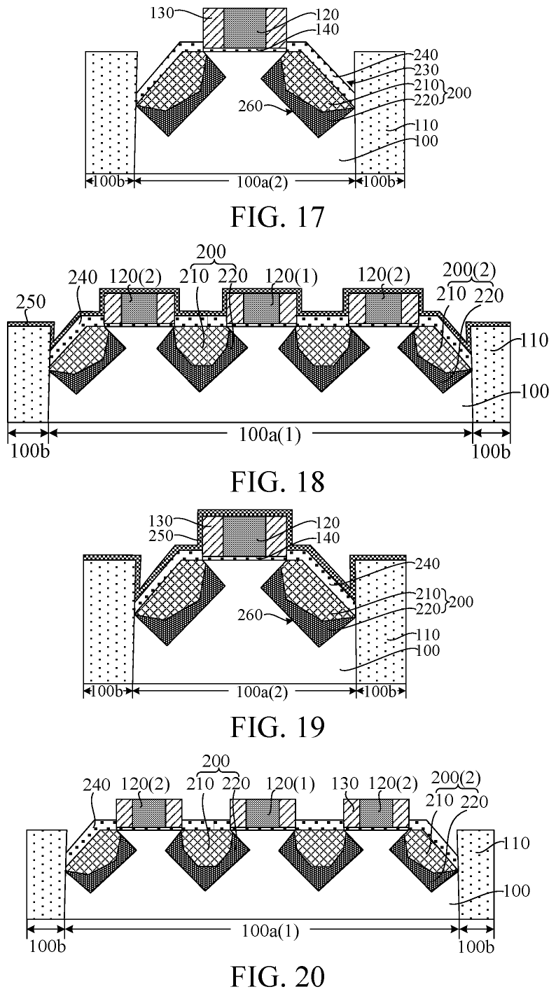

Referring to FIG. 16 and FIG. 17, the forming method of a semiconductor structure further includes: a cap layer 240 covering the surface of the source/drain bulk layer 210 is formed in the trench 230 after the formation of the source/drain doped layer 200, a material of the cap layer 240 being a silicon-containing semiconductor material.

The formation of the cap layer 240 of which the material is the silicon-containing semiconductor material can prevent the source/drain bulk layer 210 from contacting the isolation structure 110, and accordingly prevent the source/drain bulk layer 210 from contacting the isolation material, thereby effectively reducing the extension resistance of the device and improving the LOD effect.

The difference between a thermal expansion coefficient of the isolation material and a thermal expansion coefficient of the material of the source/drain bulk layer 210 is smaller than the difference between a thermal expansion coefficient of the silicon-containing semiconductor material and the thermal expansion coefficient of material of the source/drain bulk layer 210, so that the cap layer 240 made of the silicon-containing semiconductor material is formed to prevent the source/drain bulk layer 210 from contacting the isolation structure 110, which is beneficial to preventing the isolation structure 110 from producing stress on the source/drain bulk layer 210, thereby avoiding changes of electrical parameters of the device. The cap layer 240 is accordingly beneficial to maintaining the stress in the source/drain bulk layer 210, so that all the stress of the source/drain doped layer 200 can be applied to the channel area.

Besides, the material of the cap layer 240 is the silicon-containing semiconductor material. In the subsequent salicide process, the cap layer 240 is also used for reacting with the metal layer to form a metal silicide layer with lower resistance, so that the metal silicide layer is located between the source/drain doped layer 200 and the source/drain contact plug, which is beneficial to reducing the contact resistance between the source/drain doped layer 200 and the source/drain contact plug.

In this example, the material of the cap layer 240 includes silicon or SiGe. Silicon is a reactive material commonly used in the salicide process in the semiconductor technology, which is beneficial to improving the process compatibility. When the material of the cap layer 240 is SiGe, the SiGe is SiGe with a low germanium concentration, thereby ensuring that the cap layer 240 can react with the metal layer to form the metal silicide with lower resistance.

In this example, the process of forming the cap layer 240 includes a selective epitaxy growth (SEG) process. Based on the basic principle of epitaxy growth and the characteristic that it is difficult for an epitaxial material to nucleate and form a film on an insulator, the selective epitaxy growth process can epitaxially grow the epitaxial material only in specific areas of the semiconductor structure. Specifically, in this example, the exposed semiconductor material is only the surface of the source/drain bulk layer 210, so that the material of the cap layer 240 can be selectively grown on the surface of the source/drain bulk layer 210, thereby avoiding the step of removing the material of the cap layer on other layer structures and being beneficial to reducing the process complexity.

Referring to FIG. 18 and FIG. 19, in this example, the forming method of a semiconductor structure further includes: surfaces of the isolation structure 110, the cap layer 240 and the gate structure 120 are conformally covered with a stress layer 250 after the formation of the cap layer 240. Specifically, the stress layer 250 conformally covers a side wall and a top of the spacer 130.

The formed stress layer 250 is beneficial to maintaining the stress in the source/drain bulk layer 210, so that all the stress of the source/drain bulk layer 210 can be applied to the channel, which prevents stress loss of the source/drain doped layer 200, thereby ensuring the improvement of the carrier mobility in the channel area by the source/drain doped layer 200 and further improving the performance of the semiconductor structure.

In this example, the stress layer 250 is an integrated structure, which is beneficial to preventing the stress loss in the stress layer 250 and can further improve the maintenance of the stress in the source/drain bulk layer 210.

In this example, a material of the stress layer 250 includes silicon nitride. Silicon nitride is a commonly used stress film material, which is beneficial to improving the process compatibility.

In this example, a process of forming the stress layer 250 includes atomic layer deposition. The step coverage of the atomic layer deposition is beneficial to improving the conformal coverage of the stress layer 250 on the surfaces of the isolation structure 110, the cap layer 240 and the gate structure 120, and the film formed by the atomic layer deposition has the advantages of high density, good thickness uniformity, high film forming quality and less defects, which is beneficial to improving the film forming quality of the stress layer 250 and accordingly improving the maintenance of stress of the stress layer 250 on the source/drain doped layer 200.

In other examples, the stress layer may also be formed by other appropriate deposition processes (e.g., chemical vapor deposition). The chemical deposition may be plasma enhanced chemical vapor deposition (PECVD).

It would be appreciated that in this example, after the formation of the stress layer 250, the forming method further includes: the stress layer 250 is annealed.

By annealing the stress layer 250, the stress in the stress layer 250 is transferred into the source/drain doped layer 200 and the gate structure 120, and then applied to the channel through the source/drain doped layer 200 and the gate structure 120, and in the meanwhile, the stress is memorized by the source/drain doped layer 200 and the gate structure 120.

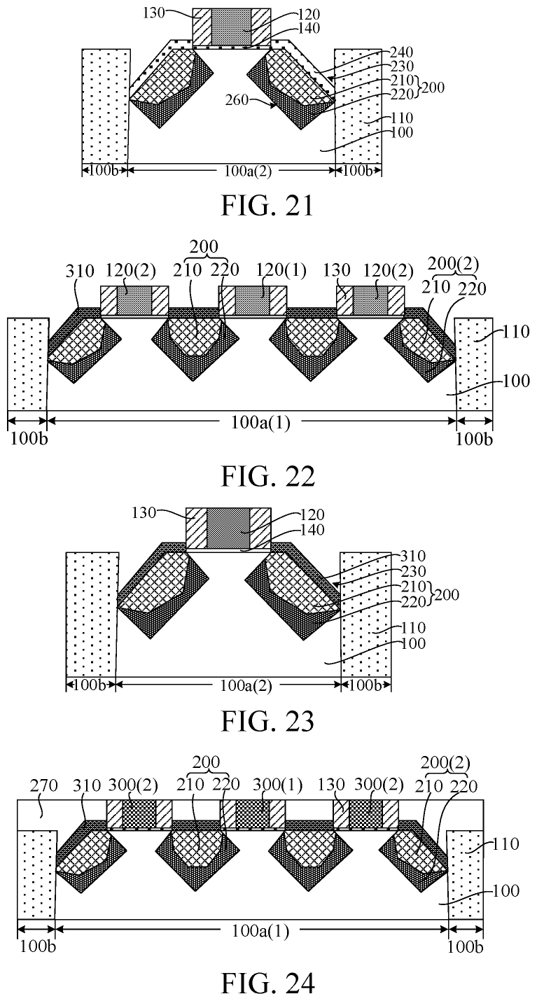

Referring to FIG. 20 and FIG. 21, in this example, the forming method of a semiconductor structure further includes: after the stress layer 250 is annealed, the stress layer 250 is removed.

During the aforementioned annealing process, the stress in the stress layer 250 has been transferred to the source/drain doped layer 200 and gate structure 120 and applied to the channel, so the removal of the stress layer 250 has little effect on the stress in the source/drain doped layer 200, the gate structure 120 and the channel. Moreover, after the stress layer 250 is removed, the top surfaces of the cap layer 240 and gate structure 120 are exposed, which facilitates the subsequent process (e.g., the salicide process).

In this example, the stress layer 250 is removed by a wet etching process. The wet etching process has the characteristics of isotropic etching, and thus can remove the stress layer 250 conformally covering the surfaces of the isolation structure 110, the cap layer 240 and the gate structure 120. In an example, a material of the stress layer 250 is silicon nitride. An etching solution used by the wet etching process may be a hot phosphoric acid solution.

Referring to FIG. 22 and FIG. 23, in this example, after the stress layer 250 is removed, the forming method of a semiconductor structure further includes: a metal layer (not shown) is formed on the top surface of the cap layer 240, the top surface of the gate structure 120, the side wall and the top surface of the spacer 130, and the top surface and a part of the side wall of the isolation structure 110; heat treatment is carried out such that the metal layer reacts with the cap layer 240 to form a metal silicide layer 310; and the remaining metal layer is removed.

The metal silicide layer 310 is used for reducing a contact resistance between the source/drain doped layer 200 and the subsequent source/drain contact plug. A material of the metal silicide layer 310 may be a nickel silicon compound, a cobalt silicon compound or a titanium silicon compound.

During the formation of the metal silicide layer 310, the metal layer only reacts with the cap layer 240, thereby realizing self-alignment of the metal silicide layer 310. Accordingly, after the formation of the metal silicide layer 310, the unreacted metal layer can be removed selectively.

In an example, during the formation of the metal silicide layer 310, the cap layer 240 completely reacts with the metal layer and is transformed into the metal silicide layer 310, so no residual cap layer 240 remains in the semiconductor structure after the formation of the metal silicide layer 310.

In other examples, after the removal of the stress layer and before the formation of the metal layer, the forming method of a semiconductor structure may further include: a side wall layer is formed on a side wall of the spacer, the side wall layer also covering a part of the top surface of the cap layer. Accordingly, during the formation of the metal silicide layer, a part of the cap layer does not react with the metal layer under the coverage of the side wall layer; and after the formation of the metal silicide layer, the part of the cap layer covered by the side wall layer is reserved in the semiconductor structure.

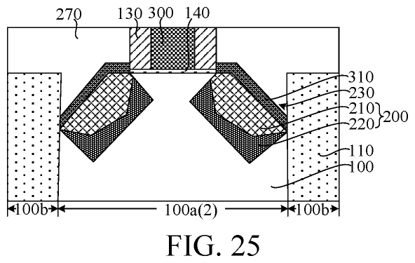

In this example, the gate structure 120 is a dummy gate. Therefore, referring to FIG. 24 and FIG. 25, the forming method of a semiconductor structure further includes: an interlayer dielectric layer 270 is formed on the substrate 100 on a side of the gate structure 120 to expose a top of the gate structure 120; the gate structure 120 is removed to form a gate opening (not shown); and a device gate structure 300 is formed in the gate opening.

The interlayer dielectric layer 270 is used for realizing electrical isolation between adjacent devices. A material of the interlayer dielectric layer 270 is a dielectric material. In this example, the material of the interlayer dielectric layer 270 is silicon oxide.

In this example, the interlayer dielectric layer 270 covers the metal silicide layer 310.

During the operation of the device, the device gate structure 300 is used for controlling a conductive channel to be on or off.

In this example, the device gate structure 300 is a metal gate structure, and the device gate structure 300 includes a high k gate dielectric layer (not shown), a work function layer (not shown) and a metal gate electrode layer (not shown) sequentially stacked from bottom to top.

A material of the high k gate dielectric layer is a high k dielectric material. The high k dielectric material is a dielectric material with a relative dielectric constant of greater than a relative dielectric constant of the silicon oxide. Specifically, the material of the high k gate dielectric layer is HfO₂. In other examples, the material of the high k gate dielectric layer may also be selected from ZrO₂, HfSiO, HfSiON, HfTaO, HfSiO, HfZrO, Al₂O₃ or the like. The work function layer is used for adjusting a work function of the device gate structure 300, thereby adjusting the threshold voltage of the device. When forming a PMOS device, the work function layer is a P-type work function layer, and a material of the P-type work function layer includes one or more of TiN, Ta, TaN, TaSiN and TiSiN. When forming an NMOS device, the work function layer is an N-type work function layer, and a material of the N-type work function layer includes one or more of TiAl, TaAlN, TiAlN, MoN, TaCN and AlN.

The gate electrode layer, serving as an electrode, is used for electrically leading out the device gate structure 300, so that the gate structure 300 can be electrically connected to an external circuit or other interconnect structures. A material of the gate electrode layer is a conductive material. The material of the gate electrode layer is Al, Cu, Ag, Au, Pt, Ni, Ti or W. In this example, the material of the gate electrode layer is W.

In this example, the number of the device gate structures 300 located in the first device cell area 100a(1) is plural; and the number of the device gate structures 300 located in the second device cell area 100a(2) is one.

It would be appreciated that in the first device cell area 100a(1), the device gate structure 300 includes a central device gate 300(1) and an edge device gate 300(2) located on an edge of the first device cell area 100a(1).

Although embodiments and implementations of the disclosure are described above, the disclosure is not limited thereto. A person skilled in the art can make various changes and modifications without departing from the spirit and the scope of the disclosure. Therefore, the protection scope of the disclosure should be subject to the scope defined by the claims.

What is claimed is:

1. A semiconductor structure, comprising:
a substrate, comprising a device cell area and an isolated area located on a periphery of the device cell area;
an isolation structure, located in the substrate of the isolated area;
a device gate structure, located on the substrate of the device cell area; and
a source/drain doped layer, embedded into the substrate of the device cell area on two sides of the device gate structure, the source/drain doped layer comprising a source/drain bulk layer, a side wall of the source/drain bulk layer located on an edge of the device cell area and the isolation structure being spaced apart.

2. The semiconductor structure according to claim 1, wherein the side wall of the source/drain bulk layer located on the edge of the device cell area on a side opposite to the isolation structure is a Miller index plane <111>.

3. The semiconductor structure according to claim 1, wherein the side wall of the source/drain bulk layer located on the edge of the device cell area has an included angle with the isolation structure and forms a trench with the isolation structure.

4. The semiconductor structure according to claim 3, wherein the semiconductor structure further comprises:
a metal silicide layer, located in the trench and covering a surface of the source/drain bulk layer.

5. The semiconductor structure according to claim 1, wherein the semiconductor structure comprises:
a groove, located in the substrate of the device cell area on the two sides of the device gate structure, the source/drain doped layer being located in the groove; and
the source/drain doped layer further comprises:
a source/drain seed layer, located between the substrate exposed by the groove and the source/drain bulk layer, a doping content of the source/drain seed layer being lower than a doping content of the source/drain bulk layer.

6. The semiconductor structure according to claim 5, wherein the groove is a Σ structure.

7. The semiconductor structure according to claim 1, wherein in response to forming a PMOS device, a material of the source/drain doped layer comprises SiGe, and
in response to forming an NMOS device, the material of the source/drain doped layer comprises SiC.

8. The semiconductor structure according to claim 1, wherein the substrate comprises a first device cell area for forming a first device and a second device cell area for forming a second device, the first device cell area and the second device cell area being isolated by the isolated area;
a plurality of device gate structures are located in the first device cell, and a single device gate structure is located in the second device cell area.

9. A forming method of a semiconductor structure, comprising:
providing a substrate, comprising a device cell area and an isolated area located on a periphery of the device cell area;
forming an isolation structure in the substrate of the isolated area;
forming a gate structure on the substrate of the device cell area after forming of the isolation structure; and
forming a source/drain doped layer in the substrate of the device cell area on two sides of the gate structure, the source/drain doped layer comprising a source/drain bulk layer, a side wall of the source/drain bulk layer located on an edge of the device cell area and the isolation structure being spaced apart.

10. The forming method of a semiconductor structure according to claim 9, wherein the step of forming the source/drain doped layer comprises:
forming a groove in the substrate of the device cell area on the two sides of the gate structure, the groove located on the edge of the device cell area exposing a part of a side wall of the isolation structure; and
forming the source/drain doped layer in the groove.

11. The forming method of a semiconductor structure according to claim 10, wherein the substrate of the device cell area on the two sides of the gate structure is etched sequentially by a dry etching process and a wet etching process to form the groove.

12. The forming method of a semiconductor structure according to claim 10, wherein the groove is a Σ structure.

13. The forming method of a semiconductor structure according to claim 10, wherein the step of forming the source/drain doped layer in the groove comprises:
forming a source/drain seed layer on a surface of the substrate exposed by the groove; and
forming the source/drain bulk layer on the source/drain seed layer, a doping content of the source/drain bulk layer being higher than a doping content of the source/drain seed layer.

14. The forming method of a semiconductor structure according to claim 13, wherein an epitaxial layer is formed by an epitaxy growth process, and ions are autodoped in situ during formation of the epitaxial layer to form the source/drain bulk layer.

15. The forming method of a semiconductor structure according to claim 14, wherein the step of forming the source/drain bulk layer comprises:
adjusting recipes of the epitaxy growth process such that the source/drain bulk layer is epitaxially grown along a Miller index orientation <111>.

16. The forming method of a semiconductor structure according to claim 15, wherein during the formation of the source/drain doped layer, the side wall of the source/drain bulk layer located on the edge of the device cell area has an included angle with the isolation structure and forms a trench with the isolation structure; and
the forming method of a semiconductor structure further comprises:
forming a cap layer covering the surface of the source/drain bulk layer in the trench after the formation of the source/drain doped layer, a material of the cap layer being a silicon-containing semiconductor material.

17. The forming method of a semiconductor structure according to claim 16, wherein the forming method of a semiconductor structure further comprises:
conformally covering surfaces of the isolation structure, the cap layer and the gate structure with a stress layer after the formation of the cap layer.

18. The forming method of a semiconductor structure according to claim 17, wherein the forming method of a semiconductor structure further comprises:
annealing the stress layer after the formation of the stress layer.

19. The forming method of a semiconductor structure according to claim 9, wherein in the step of providing the substrate, the substrate comprises a first device cell area for forming a first device and a second device cell area for forming a second device, the first device cell area and the second device cell area being isolated by the isolated area; and
in the step of forming the gate structure, a plurality of gate structures are formed in the first device cell area, and a single gate structure is formed in the second device cell area.

20. The forming method of a semiconductor structure according to claim 9, wherein the gate structure is a dummy gate, and after the formation of the source/drain doped layer, the forming method of a semiconductor structure further comprises:
forming an interlayer dielectric layer on the substrate on a side of the gate structure to expose a top of the gate structure;
removing the gate structure to form a gate opening in the interlayer dielectric layer; and
forming a device gate structure in the gate opening.
